(19) United States
(12) Patent Application Publication
(10) Pub. No.: US 2002/0079086 A1
(43) Pub. Date: Jun. 27, 2002

(54) Embedded centrifugal cooling device

(75) Inventors: Wen-Shi Huang, Taoyuan Hsien (TW); Kuo-Cheng Lin, Taoyuan Hsien (TW); Tsu-Liang Lin, Taoyuan Hsien (TW); Tsung-Yu Lei, Taoyuan Hsien (TW)

Correspondence Address: INTELLECTUAL PROPERTY SOLUTIONS, P.L.L.C., 1300 PENNSYLVANIA AVENUE N.W., SUITE 700, WASHINGTON, DC, 20004, US

(73) Assignee: DELTA ELECTRONICS INC., Taoyuan Sien 333 (TW)

(21) Appl. No.: 09/930,990

(22) Filed: Aug. 17, 2001

(30) Foreign Application Priority Data
Dec. 27, 2000 (TW) 89222512

(51) Int. Cl. F28F 7/00; H05K 7/20; H01L 23/34

(52) U.S. Cl. 165/80.3; 165/185; 361/697; 257/722

(57) ABSTRACT

An embedded centrifugal cooling device is disclosed. The embedded centrifugal cooling device includes a heat sink and a centrifugal fan. The heat sin includes a plurality of cooling fins defining a cavity. The centrifugal fan is formed in the cavity so as to be embedded into the heat sink. The present invention further includes a cover formed on the heat sink and the centrifugal fan to keep airtight substantially.

### BACKGROUND OF THE INVENTION

1. Field of the Invention

The present invention relates to a cooling device, and more particularly to an embedded centrifugal cooling device.

2. Description of the Prior Art

Generally, the cooling device is attached to the surface of a heat-generating device to dissipate the heat therefrom.

As shown in FIG. 1(a), a conventional cooling device 10 includes a axial-flow fan 50 and a heat sink 60. Among these, the axial-flow fan 50 is composed of a hub 53 and a plurality of blades 55. Especially, the heat sink 60 includes an upper surface having the axial-flow fan 50 mounted thereto, and a lower surface having a heat-generating device such as a CPU (not shown) attached thereon. Therefore, the hub 53 is positioned above the central region of the heat-generating device and the blades 55 the peripheral region surrounding the central region. The disadvantages of such the conventional cooling device 10 at least include poor or uneven cooling effect, defective flow field as well as bulky volume, and they are described as follows.

FIG. 1(b) shows the cross-sectional view illustrating the conventional cooling device 10 and the corresponding curve of temperature distribution. The peak of the curve of temperature distribution mainly appears on the central region of the heat-generating device. Then, the amplitude gradually decays along the direction toward the peripheral region. Unfortunately, due to the configuration of the conventional cooling device 10, the central region of the heat-generating device suffers the worst cooling effect compared to the peripheral region. Because the central region is positioned under the hub 53 which does not contribute to forming the coolant air dissipating heat.

Further, due to the configuration of the axial-flow fan 50 equipped by the conventional cooling device 10, the coolant air, as indicated by the arrow, directed by the axial-flow fan 50 impacts the heat-generating device and then is exhausted through the side of the heat sink 60. In this case, the flow field of the coolant air is forced and irregular. Moreover, the flow rate of the coolant air is restricted and thus slowed.

Stilling referring to FIG. 1(a), further, the conventional cooling device 10 is bulky. Since the axial-flow fan 50 is attached to the surface of the heat sink 60, the thickness of the conventional cooling device 10 equals to the thickness of the axial-flow fan 50 plus the thickness of the heat sink 60.

Referring to FIG. 1(c), U.S. Pat. No. 5,661,638 discloses another conventional cooling device 20. The conventional cooling device 20 is composed of an axial-flow fan 50 and a heat sink 60. Among these, the axial-flow fan 50 is composed of a hub 53 and a plurality of blades 55. Especially, the heat sink 60 includes a plurality of spiral cooling fins 65 surrounding around the axial-flow fan 50. The axial-flow fan 50 is embedded into the heat sink 60. However, besides uneven cooling effect and defective flow field, the drawback of the conventional cooling device 20 further includes poor airtight. Since the reasons causing uneven cooling effect and defective flow field is the same with that of the conventional cooling device 10 shown in FIG. 1(a) and has been described above, giving unnecessary details is omitted.

Still referring to FIG. 1(c), since the coolant air of the conventional cooling device 20 is exhausted before reaching the outer periphery of the cooling fins 65, the coolant air fails to blow most portions of the cooling fins 65.

FIG. 1(d) also shows another conventional cooling device 30. The conventional cooling device 30 is composed of a heat sink 50 and a centrifugal fan 60. The centrifugal fan 60 is attached to one side of the heat sink 50 so as to reduce the thickness of the conventional cooling device 30. However, such the configuration increases the projection area of the conventional cooling device 30. Furthermore, since the distance from each position of the heat sink 50 to the centrifugal fan 60 varies, the cooling effect has a reverse proportion to the distance from the heat sink 50 to the centrifugal fan 60. The coolant air may fail to blow the position of the heat sink 50 that is the most away form the cooling fins 65.

Accordingly, there has been a strongly felt need for improvements in the conventional cooling device.

### SUMMARY OF THE INVENTION

Therefore, the main object of the present invention is to provide an embedded centrifugal cooling device can overcome aforementioned problems.

The present embedded centrifugal cooling device is attached to the surface of a heat-generating device so as to dissipate the heat.

The present embedded centrifugal cooling device includes a heat sink, a blower or a centrifugal fan and a cover. Among these, the heat sink includes a plurality of cooling fins and a cavity defined by the cooling fins. The centrifugal fan is formed in the cavity such that the centrifugal fan is embedded into the heat sink. It is noted that the shape of the cavity matches that of the centrifugal fan. In this manner, the cooling fins are distributed under the region extending form the central region to the peripheral region of the centrifugal fan. The heat sink is made of the material chosen from the group consisting of aluminum, aluminum alloy, copper, copper alloy and the combination thereof.

The heat sink is used to previously direct the heat concentrated in the central region of the heat-generating device to a larger heat-dissipating surface. Then, using the centrifugal fan to blow the heat sink so as to direct the heat to ambiance. It is noted that since the cooling fins are also distributed under and around the central region of the centrifugal fan, the heat mainly concentrated in the central region of the heat-generating device is dissipated effectively.

Further, the present embedded centrifugal cooling device includes a cover formed over the heat sink and the centrifugal fan. The cover serves as an air seal to keep the present embedded centrifugal cooling device airtight substantially. In this manner, the coolant air generated by the centrifugal fan can blow substantially the total length of the cooling fins and then exhaust in the outer periphery of the cooling fins.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1(a) shows a conventional cooling device;

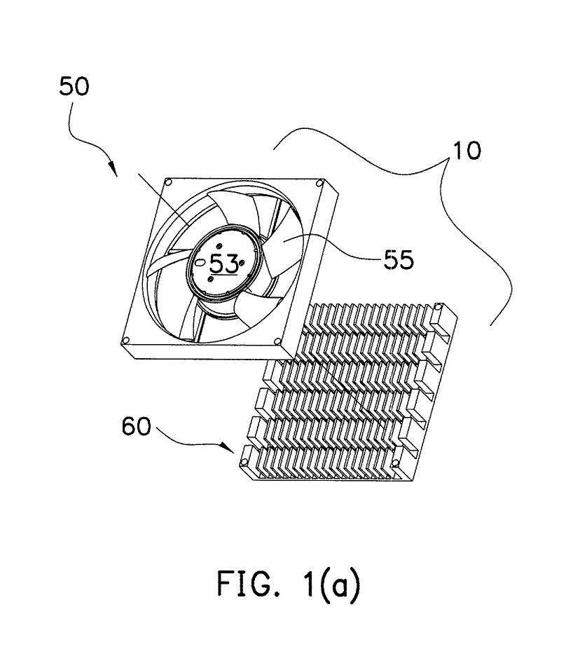

FIG. 1(b) shows a cross-sectional view illustrating the conventional cooling device shown in FIG. 1(a), and a corresponding curve depicting the temperature distribution;

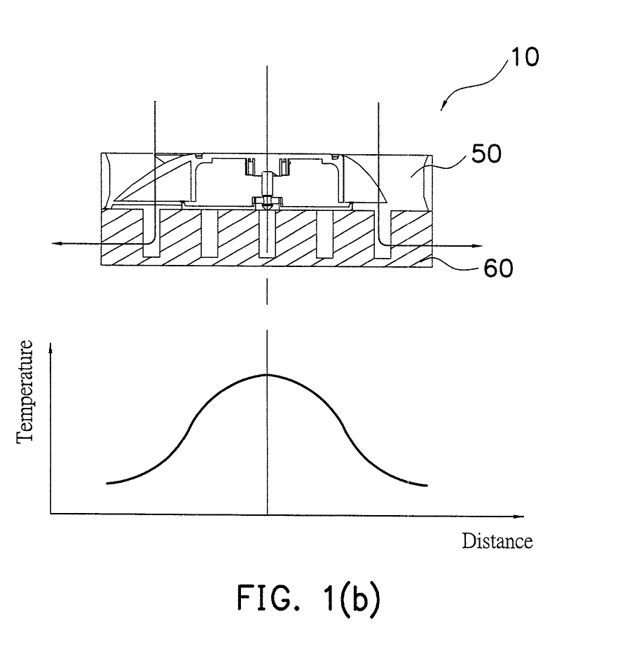

FIG. 1(b) shows another conventional cooling device;

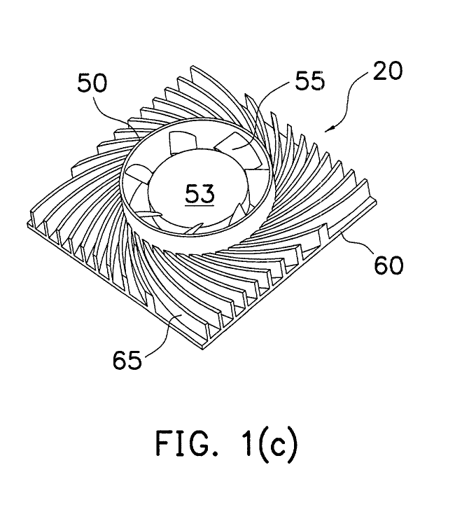

FIG. 1(c) also shows another conventional cooling device

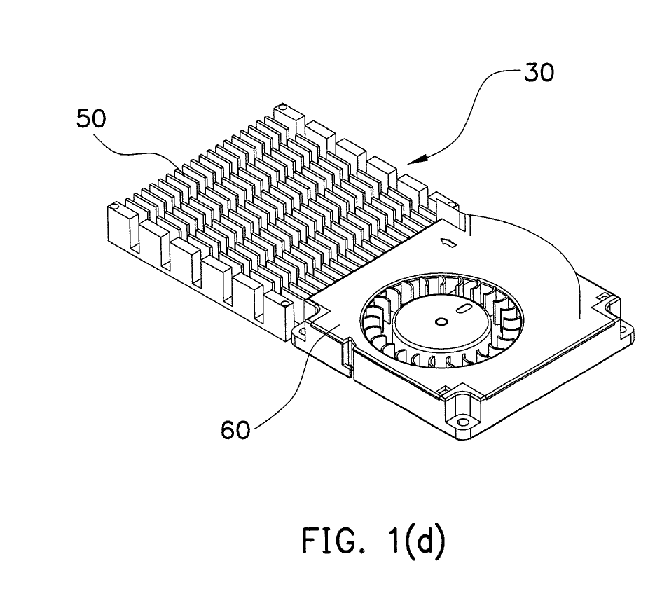

FIG. 2(a) shows a exploded view according to the present invention;

FIG. 2(b) shows a top plan view illustrating the cavity according to the present invention; and

FIG. 3 shows a cross-sectional view according to the present invention, and a corresponding curve depicting the temperature distribution.

### DESCRIPTION OF THE PREFERRED EMBODIMENT

The present embedded centrifugal cooling device is attached to the surface of a heat-generating device such as a CPU (not shown) so as to dissipate the heat therefrom.

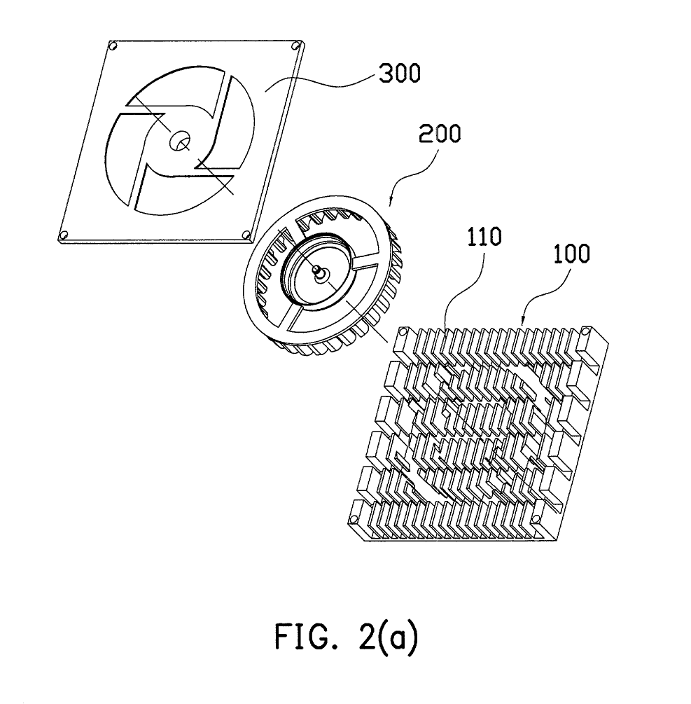

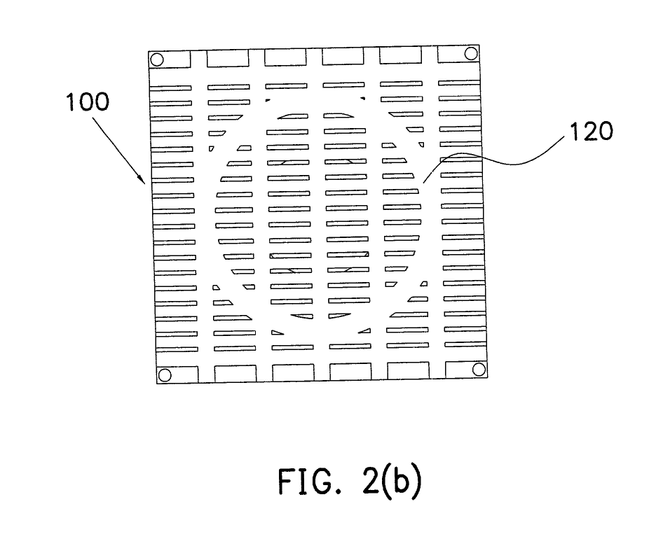

As shown in FIG. 2(a), the present embedded centrifugal cooling device includes a heat sink 100, a blower or a centrifugal fan 200 and a cover 300. Among these, the heat sink 100 includes a plurality of cooling fins 110 and a cavity 120 defined by the cooling fins 110, as shown in FIG. 2(b). The centrifugal fan 200 is formed in the cavity 120 such that the centrifugal fan 200 is embedded into the heat sink 100. It is noted that the shape of the cavity 120 matches that of the centrifugal fan 200. In this manner, the cooling fins 110 are distributed under and around the region extending form the central region to the peripheral region of the centrifugal fan 200. The heat sink 100 is made of material chosen from the group consisting of aluminum, aluminum alloy, copper, copper alloy and the combination thereof.

Still referring to FIG. 2(a), the heat sink 100 is used to previously direct the heat concentrated in the central region of the heat-generating device to a larger heat dissipating surface (e.g. cooling fins). Then, using the centrifugal fan 200 to blow the heat sink 100 so as to direct the heat to ambiance. It is noted that since the cooling fins 110 are also distributed under the central region of the centrifugal fan 200, the heat mainly concentrated in the central region of the heat-generating device is dissipated effectively.

Further, the present embedded centrifugal cooling device includes a cover 300 formed over the heat sink 100 and the centrifugal fan 200. The cover 300 serves as an air seal to keep the present embedded centrifugal cooling device airtight substantially. In this manner, the coolant air generated by the centrifugal fan 200 can blow substantially the total length of the cooling fins 110 and then exhaust in the outer periphery of the cooling fins 110.

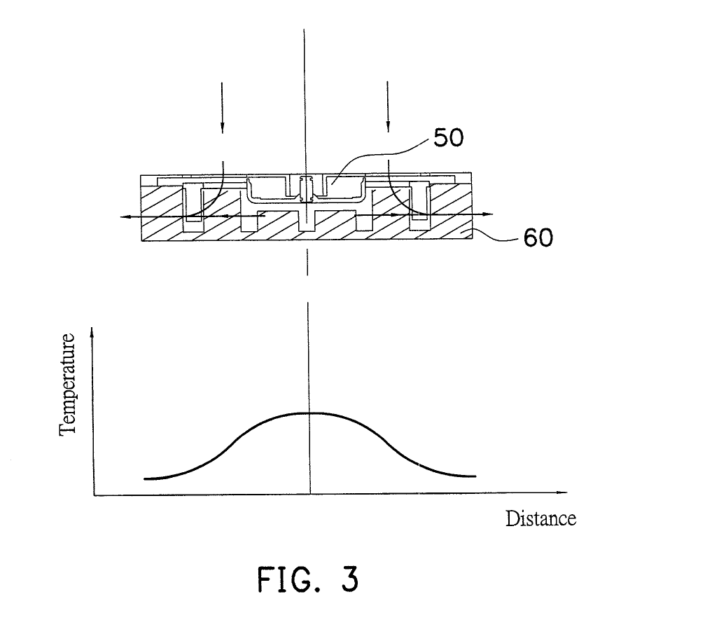

FIG. 3 shows the cross-sectional view illustrating the present invention and a corresponding curve depicting the temperature distribution of the heat-generating device. According to the above-mentioned detailed description, the temperature distribution curve of the present invention is more planar compared to that of prior art. Besides, the present invention has a relatively low profile and a small area compared to the conventional cooling device.

It is noted that although the present centrifugal fan 200 includes a hub, the hub does not affect the cooling effect of the centrifugal fan 200 since the centrifugal fan 200 is characterized that the coolant air radially flows form the central region to the peripheral region. Alternatively, the centrifugal fan without hub is also used. Since the centrifugal fan without hub has already existed, the detailed description is omitted.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1.An embedded centrifugal cooling device, comprising:
a heat sink, including cavity; and
a centrifugal fan, formed in said cavity.

2.The embedded centrifugal cooling device according to claim 1, wherein said heat sink further comprises a plurality of cooling fins defining said cavity.

3.The embedded centrifugal cooling device according to claim 2, wherein said cooling fins are distributed under and around a region extending form a central region of said centrifugal fan to a periphery of said centrifugal fan.

4.The embedded centrifugal cooling device according to claim 1, further comprises a cover formed on said heat sink and said centrifugal fan.

5.The embedded centrifugal cooling device according to claim 4, wherein said cover serves as an air seal to keep airtight.

6. The embedded centrifugal cooling device according to claim 1, wherein said cavity matches said centrifugal fan.

7.The embedded centrifugal cooling device according to claim 1, where in said heat sink is made of a material chosen from the group consisting of aluminum, aluminum alloy, copper, copper alloy and the combination thereof.

8.An embedded centrifugal cooling device, comprising:
a heat sink, including a plurality of cooling fins, said cooling fins defining a cavity; and
a centrifugal fan, formed in said cavity so as to be embedded into said heat sink.

9.The embedded centrifugal cooling device according to claim 8, further comprises a cover formed on said heat sink and said centrifugal fan.

10.The embedded centrifugal cooling device according to claim 8, wherein said cover serves an air seal to keep airtight.

11.The embedded centrifugal cooling device according to claim 8, wherein said cavity matches said centrifugal fan.

12.The embedded centrifugal cooling device according to claim 8, wherein said cooling fins are distributed under and around a region extending form a central region of said centrifugal fan to a periphery of said centrifugal fan.

13.The embedded centrifugal cooling device according to claim 8, wherein said heat sink is made of a material chosen from the group consisting of aluminum, aluminum alloy, copper, copper alloy and the combination thereof.

14.An embedded centrifugal cooling device, comprising:
a heat sink, including a plurality of cooling fins, said cooling fins defining a cavity;
a centrifugal fan, formed in said cavity so as to be embedded into said heat sink; and
a cover formed on said heat sink and said centrifugal fan.

15.The embedded centrifugal cooling device according to claim 14, wherein said cover serves as an air seal to keep airtight.

16.The embedded centrifugal cooling device according to claim 14, wherein said cavity matches said centrifugal fan.

17.The embedded centrifugal cooling device according to claim 14, wherein said cooling fins are distributed under and around a region extending form a central region of said centrifugal fan to a periphery of said centrifugal fan.

18.The embedded centrifugal cooling device according to claim 14, wherein said heat sink is made of a material chosen from the group consisting of aluminum, aluminum alloy, copper, copper alloy and the combination thereof.
